(19) United States
(12) Patent Application Publication
(10) Pub. No.: US 2013/0167903 A1
(43) Pub. Date: Jul. 4, 2013

(54) ENCAPSULATED SOLAR ENERGY CONCENTRATOR

(71) Applicant: Prism Solar Technologies Incorporated, Highland, NY (US)

(72) Inventors: Eric D. Aspnes, Tucson, AZ (US); Jose E. Castillo, Tucson, AZ (US); Ryan D. Courreges, Tucson, AZ (US); Daniel C. Fox, Duvall, WA (US); Paul S. Hauser, Tucson, AZ (US); Glenn Rosenberg, Tucson, AZ (US); Jeffrey W. Rosenberg, Tucson, AZ (US); Juan Manuel Russo, Tucson, AZ (US)

(73) Assignee: Prism Solar Technologies Incorporated, Highland, NY (US)

(21) Appl. No.: 13/682,119

(22) Filed: Nov. 20, 2012

Related U.S. Application Data
(63) Continuation-in-part of application No. 13/675,855, filed on Nov. 13, 2012.
(60) Provisional application No. 61/563,339, filed on Nov. 23, 2011.
(60) Provisional application No. 61/559,980, filed on Nov. 15, 2011.
(60) Provisional application No. 61/559,425, filed on Nov. 14, 2011.
(60) Provisional application No. 61/560,381, filed on Nov. 16, 2011.
(60) Provisional application No. 61/562,654, filed on Nov. 22, 2011.

(51) Int. Cl. H01L 31/052; G02B 5/32

(52) U.S. Cl. CPC H01L 31/0527; G02B 5/32
USPC 136/246; 136/259; 359/15

(57) ABSTRACT

A holographic planar concentrator of solar energy employing an array of holographically-recorded diffraction grating elements adjoining the corresponding bifacial or monofacial PV-cell. Diffracting grating elements are configured to operate in transmission and/or reflection. The array is sandwiched and, optionally, encapsulated between the two layers of structurally supporting material that are impermeable to ambient moisture. The grating elements can be blazed and the material layer in which the gratings are recorded is protected from the moisture in the ambient environment by a moisture impermeable encapsulant.

### CROSS-REFERENCE TO RELATED APPLICATIONS

The present application claims benefit of and priority from the U.S. Provisional Patent Application No. 61/563,339 filed on Nov. 23, 2011 and titled “Encapsulated Solar Energy Concentrator”. The present application is a continuation-in-part of the commonly assigned U.S. patent application Ser. No. 13/675,855 filed on Nov. 13, 2012 and titled “Flexible Photovoltaic Module”. The above-mentioned U.S. patent application Ser. No. 13/675,855 claims priority from U.S. Provisional Patent Applications Nos. 61/559,980 titled “Flexible Crystalline PV Module Configurations” and filed on Nov. 15, 2011; Nos. 61/559,425 filed on Nov. 14, 2011 and titled “Advanced Bussing Options for Equal Efficiency Bifacial Cells”; 61/560,381 filed on Nov. 16, 2011 and titled “Volume Hologram Replicator for Transmission Type Gratings”; and 61/562,654 filed on Nov. 22, 2011 and titled “Linear Scan Modification to Step and Repeat Holographic Replicator”. The disclosure of each of the above-mentioned patent applications is incorporated herein by reference in its entirety.

### TECHNICAL FIELD

The present invention relates to photo-voltaic conversion of solar radiation and, in particular, to an encapsulated holographic planar concentrator of solar energy.

### BACKGROUND ART

Solar energy will satisfy an important part of future energy needs. While the need in solar energy output has grown dramatically in recent years, the total output from all solar installations worldwide still remains around 7 GW, which is only a tiny fraction of the world's energy requirement. High material and manufacturing costs, low solar module efficiency, and shortage of refined silicon limit the scale of solar power development required to effectively compete with the use of coal and liquid fossil fuels.

The key issue currently faced by the solar industry is how to reduce system cost. The main-stream technologies that are being explored to improve the cost-per-kilowatt of solar power are directed to (i) improving the efficiency of a solar cell that comprises solar modules, and (ii) delivering greater amounts of solar radiation onto the solar cell. In particular, these technologies include developing thin-film, polymer, and dye-sensitized photovoltaic (PV) cells to replace expensive semiconductor material based solar cells, the use high-efficiency smaller-area photovoltaic devices, and implementation of low-cost collectors and concentrators of solar energy.

While the reduction of use of semiconductor-based solar cells is showing great promise, for example, in central power station applications, it remains disadvantageous for residential applications due to the form factor and significantly higher initial costs. Indeed, today's residential solar arrays are typically fabricated with silicon photovoltaic cells, and the silicon material constitutes the major cost of the module. Therefore techniques that can reduce the amount of silicon used in the module without reducing output power will lower the cost of the modules.

The use of devices adapted to concentrate solar radiation on a solar cell is one of such techniques. Various light concentrators have been disclosed in related art, for example a compound parabolic concentrator (CPC); a planar concentrator such as, for example, a holographic planar concentrator (HPC) including a planar highly transparent plate and a holographically-recorded optical element mounted on its surface; and a spectrum-splitting concentrator (SSC) that includes multiple, single junction PV cells that are separately optimized for high efficiency operation in respectively-corresponding distinct spectral bands. A conventionally-used HPC is deficient in that the collection angle, within which the incident solar light is diffracted to illuminate the solar cell, is limited to about 45 degrees. Production of a typical SSC, on the other hand, requires the use of complex fabrication techniques.

In most of the existing systems used for concentration of solar radiation that employ holographic diffractive gratings, the material of choice for fabrication of such gratings has included dichromated gelatin emulsion that is quite hydrophilic. The resulting holographic gratings have to be sealed from the environment, which inevitably increases the cost of manufacture and final product packaging of the overall system. The need in diffractive devices, for use in solar energy concentration systems, that are insensitive to the environment are, therefore, required.

### SUMMARY OF THE INVENTION

Embodiments of the present invention provide a photovoltaic (PV) module that includes (i) a PV cell having a first photo-voltaically operable surface; (ii) a first encapsulant material covering said first photo-voltaically operable surface; and (iii) a holographic grating element adjacent to and substantially coplanar with the PV cell. The holographic grating element includes a holographic grating embedded in a second encapsulant material. The PV module additionally includes a first optically transparent cover disposed in optical contact with the first encapsulant layer such as to extend extending over the holographic grating element. The combination of the first optically transparent cover and the holographic grating element are dimenstioned to ensure that r light, that has been received by the holographic grating element through the first optically transparent cover at about normal incidence, is reflected along a path defined by total internal reflection in the first optically transparent cover and ending at the first photo-voltaically operable surface. The embodiment of the PV module optionally additionally includes an (optionally flexible) backsheet adhered to the PV cell along a surface opposite to the first photo-voltaically operable surface.

The holographic grating element includes at least one a volume hologram recorded in a gelatin material and a stamped metal hologram. In one embodiment, the second encapsulant material defines the backsheet and/or is substantially moisture-impermeable. In a related embodiment, the PV cell includes a bifacial PV cell having a second photo-voltaically operable surface, and the PV module additionally contains a second optically-transparent cover disposed adjacently to the second photo-voltaically operable surface such as to extend along the holographic grating element. The second optically-transparent cover and the holographic grating element are configured such as to reflect light, that has been received by the holographic grating element through the first optically transparent cover at about normal incidence, along a path defined by total internal reflection in the second optically transparent cover and ending at the second photo-voltaically operable surface.

Embodiments of the invention additionally provide a photovoltaic (PV) module that includes (i) a bifacial PV cell having first and second operational surfaces; encapsulting materials disposed to cover the first and second surfaces; (ii) first and second optical substrates positioned to sandwich said bifacial PV cell with encapsulant layers disposed thereon, each of said first and second optical substrates being in optical contact with a corresponding encapsulant layer; (iii) a holographic diffraction grating element configured to operate in transmission, such diffraction grating element being adjacent to and substantially coplanar with the PV cell between the first and second substrates. Additionally, such diffraction grating element is configured to redirect light, incident thereon through the first cover at a substantially normal incidence, along a path defined by total internal reflection in the second substrate and ending at the second operational surface. Additionally or alternatively, the diffraction grating element is embedded in an encapsulant layer that adheres said PV cell to the first and second substrates.

Embodiments of the invention additionally provide a diffraction element that includes a layered optically-transparent structure containing a first photosensitive material with a diffraction grating holographically-defined; and second and third substantially moisture-impermeable materials sandwiching the first material therebetween. The diffraction element may include an array of such layered optically-transparent structures sharing at least one layer.

### BRIEF DESCRIPTION OF THE DRAWINGS

FIG. 1 is a schematic of a holographic planar concentrator.

FIG. 2A shows an embodiment of a holographic spectrum-splitting device.

FIG. 2B shows an alternative embodiment of a holographic spectrum-splitting device.

FIG. 3A is a schematic of an embodiment of a holographic planar concentrator employing a monofacial PV cell.

FIG. 3B shows an example of structure of a holographic layer containing a diffractive grating, according to an embodiment of the invention.

FIG. 3C is an HPC-embodiment including three portions, each of which is configured in a fashion similar to that of the embodiment of FIG. 3A.

FIG. 4 is an embodiment of the invention employing a bifacial PV-cell.

FIG. 5 is a top view of the embodiment of FIG. 4

FIG. 6 is a cross sectional schematic showing the layers of a conventional PV cell.

FIG. 7 is an alternative embodiment of the invention employing a monofacial PV-cell.

### DETAILED DESCRIPTION OF PREFERRED EMBODIMENTS

References throughout this specification to “one embodiment,” “an embodiment,” “a related embodiment,” or similar language mean that a particular feature, structure, or characteristic described in connection with the referred to “embodiment” is included in at least one embodiment of the present invention. Thus, appearances of the phrases “in one embodiment,” “in an embodiment,” and similar language throughout this specification may, but do not necessarily, all refer to the same embodiment. It is to be understood that no portion of disclosure, taken on its own and in possible connection with a figure, is intended to provide a complete description of all features of the invention.

In addition, the following disclosure may describe features of the invention with reference to corresponding drawings, in which like numbers represent the same or similar elements wherever possible. In the drawings, the depicted structural elements are generally not to scale, and certain components are enlarged relative to the other components for purposes of emphasis and understanding. It is to be understood that no single drawing is intended to support a complete description of all features of the invention. In other words, a given drawing is generally descriptive of only some, and generally not all, features of the invention. A given drawing and an associated portion of the disclosure containing a description referencing such drawing do not, generally, contain all elements of a particular view or all features that can be presented is this view, for purposes of simplifying the given drawing and discussion, and to direct the discussion to particular elements that are featured in this drawing. A skilled artisan will recognize that the invention may possibly be practiced without one or more of the specific features, elements, components, structures, details, or characteristics, or with the use of other methods, components, materials, and so forth. Therefore, although a particular detail of an embodiment of the invention may not be necessarily shown in each and every drawing describing such embodiment, the presence of this detail in the drawing may be implied unless the context of the description requires otherwise. In other instances, well known structures, details, materials, or operations may be not shown in a given drawing or described in detail to avoid obscuring aspects of an embodiment of the invention that are being discussed. Furthermore, the described single features, structures, or characteristics of the invention may be combined in any suitable manner in one or more further embodiments.

Moreover, if the schematic flow chart diagram is included, it is generally set forth as a logical flow-chart diagram. As such, the depicted order and labeled steps of the logical flow are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow-chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Without loss of generality, the order in which processing steps or particular methods occur may or may not strictly adhere to the order of the corresponding steps shown.

The invention as recited in claims appended to this disclosure is intended to be assessed in light of the disclosure as a whole, including features disclosed in prior art to which reference is made.

As broadly used and described herein, the reference to a layer as being “carried” on or by a surface of an element refers to both a layer that is disposed directly on the surface of that element or disposed on another coating, layer or layers that are, in turn disposed directly on the surface of the element.

Embodiments of the present invention provide a system and method for delivering solar radiation towards the photovoltaic (PV) cell with the use of a diffractive device employing a blazed grating that is encapsulated with a metallic layer and is optionally coplanar with the PV-cell. Such grating lends itself to being produced in a stamped roll-to-roll process.

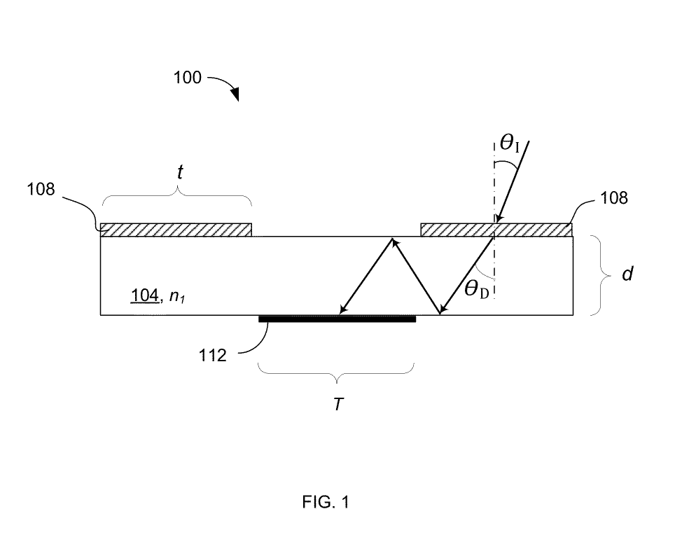

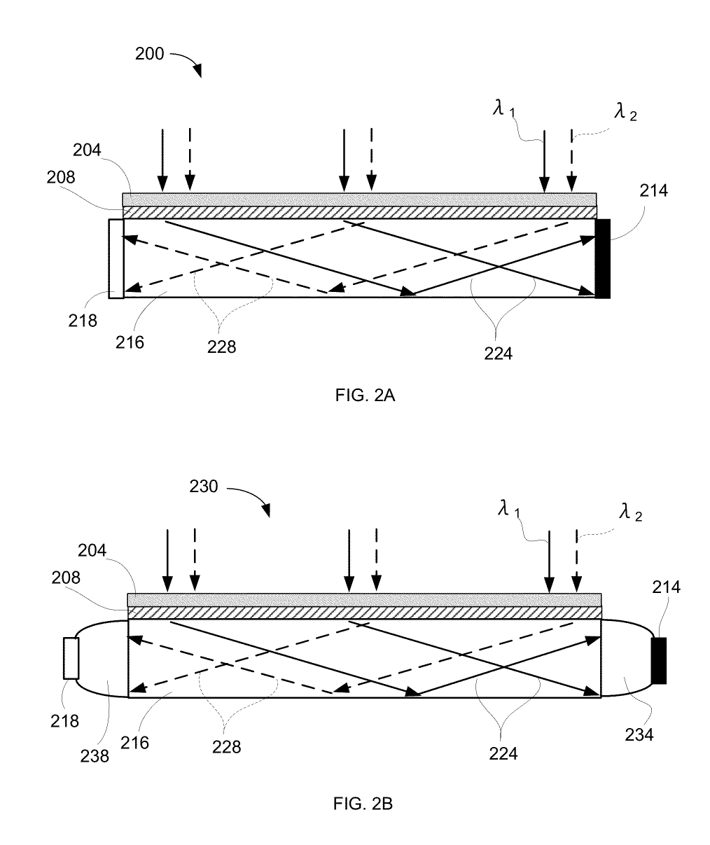

Typical devices currently used for concentration of solar radiation for the purposes of PV-conversion are shown schematically in FIGS. 1, 2A, and 2B. For example, an HPC 100 of FIG. 1, shown in a cross-sectional view, typically includes a highly-transparent planar substrate 104 of thickness d (such as, for example, substrate made of glass or appropriate polymeric material having the refractive index n₁) at least one diffractive structure 108, having width t, at a surface of the substrate 104. Such diffractive structure may include, for example, a holographic optical film (such as gelatin-on-PET film stack) in which a plurality of multiplexed diffraction gratings have been recorded with the use of laser light. The diffractive structure 108 can be optionally capped with a protective cover layer (not shown). The substrate 104 is typically cooperated with a solar-energy-collecting device 112 such as a PV cell. The diffractive structures 108 diffract wavelengths usable by the PV cell 112, while allowing the light at unusable wavelength to pass through, substantially unabsorbed. The usable energy is guided via the total internal reflection at the glass/air or glass/cover interface to strings of solar cells, resulting in up to a 3× concentration of solar energy per unit area of PV material.

Further in reference to FIG. 1, the PV cell 112 of width T is juxtaposed with the second surface of the substrate 104 in opposition to the diffractive structures 108 and in such orientation that ambient (sun-) light I, incident onto the structure 108 at an angle θ_{I}, is diffracted at an angle θ_{D} onto the cell 112 either directly or upon multiple reflections within the substrate 104. To estimate the range of incident angles that would produce the diffracted light intersecting the surface of the PV cell 112 for different parameters of the HPC 100 such as substrate thickness, the displacement of the PV cell 112 with respect to the edge of the grating 108, other geometrical parameters one can use the grating equation. For example, for a glass substrate 104 and when t=T=d, the range of incident angles (the collection angle) at which the cell 112 is illuminated is about 45 degrees. When t=2T=2d, the collection angle is reduced to about 38 degrees. The angular range within which the corresponding diffracted light is produced is about 10° to 15° for most of the wavelengths. However, the angle-wavelength matching can be used to extend this range for different portions of the available spectral bandwidth of the HPC 100.

The increase in PV-conversion efficiency, in comparison with a use of a conventional PV-cell, is also achieved by using multiple junction cells that create electron-hole pairs at the expense of energy of incident light over a wider spectral range than a single junction cell. The use of a holographic grating with such spectrum-splitting devices (SSD) also offers some advantages. The hologram is usually designed to diffract light within a specific spectral band in a desired direction (for example, towards one PV-cell) and be multiplexed with another hologram that diffracts light of different wavelength in another direction (for example, towards another PV-cell). One example of such holographic SSD 200, shown in FIG. 2A, includes two diffractive structures 204 and 208 such as diffractive gratings, holographically-recorded in a medium that usually includes gelatin-based material. The gratings 204 and 208 are cascaded at a surface 212 of the substrate 216 (i.e., at the input of the SSD 200) and that diffract light of different wavelengths. For example, the upper hologram 204 diffracts light at wavelength λ₁ longer than wavelength λ₂ diffracted by the hologram 208. Two PV-cells, respectively-corresponding to the holograms 204 and 208—a long-wavelength PV cell 214 and a short-wavelength PV-cell 218—are positioned transversely with respect to the holograms 204, 208 (as shown, at side facets of the substrate 216). Directionally-diffracted towards target PV-cells light 224, 228 reaches the PV-cells via reflections off the surfaces of the substrate 216. A simple light-concentrating reflector can additionally be used. A similar SSD 230, upgraded with cylindrical parabolic reflectors 234, 238 that guide the diffracted light towards target PV-cells, is depicted in FIG. 2B. In both cases, the collection angle is determined by geometry of the system and the diffraction characteristics of the holograms.

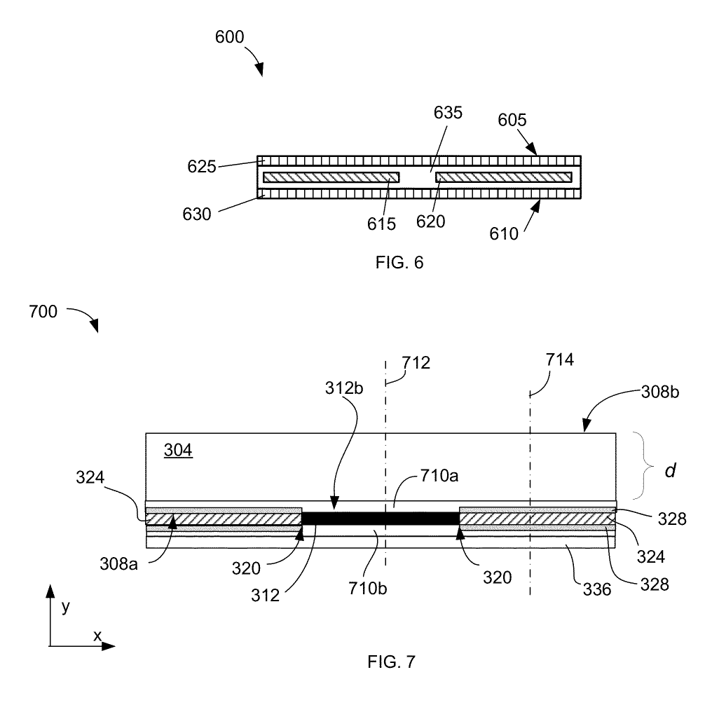

FIG. 6 is a diagram showing, in cross-sectional view, a typical bifacial PV element 600. The element 600 of FIG. 6 has a first side 605 and a second side 610. The active photo-voltaic conversion is performed by one or more PV-cells 615, 620 of the element 600, at least one of which includes, for example, doped silicon. The PV-cells are thin and delicate, they are susceptible to breakage or other damage (such as damage due to scratching, chemical etching, or other external influence). Accordingly, PV-cells are encapsulated and laminated to glass to form a typical bifacial-PV-cell-based element. In the example of FIG. 6, the element 600 is fabricated by sandwiching the PV-cells 615, 620 between first and second pieces of glass 625, 630. Interfaces between the PV-cells 615, 620 and the pieces of glass 625, 630 are supplemented with encapsulant material (or, for simplicity, encapsulant) 635. The encapsulant 635 is an optically and, optionally, IR clear adhesive such as ethyl vinyl acetate (“EVA”) or silicone. In one embodiment, the encapsulant 635 is provided in a form of two sheets of EVA that are laminated to first and second sides of the individual PV-cells. The resulting assembly is laminated to glass substrates or pieces. It is appreciated that the lamination procedure can be performed in a different sequence of steps. In the case of a monofacial cell, a backsheet made of some polymeric material (for example, polyethylene terephthalate or PET) is provided to which the PV chips are adhered. The so-formed structure can be laminated to a front side lite of glass together with an encapsulant. In some embodiments, a backsheet is provided with encapsulant pre-deposited thereon. In other typical embodiments, the glass sheet is used as a backsheet, even in case of a monofacial cell.

In contradistinction with the above-mentioned structures containing PV cells, embodiments of the present invention additionally incorporate light-concentrating holographic layers within or at the encapsulant layer(s), which holographic layers redirect light not intercepted by a solar cell toward a solar cell for conversion. According to one embodiment of the invention, a pre-patterned sheet of encapsulant material having embedded light-concentrating layers is provided for use in laminating PV chips to glass and/or a backsheet. In a related embodiment, a pre-patterned hologram is provided with encapsulant material carried by the backsheet material for use in laminating monofacial PV chips to glass. Embodiments of the invention provide the advantage over the above-described typical structure in that these embodiments ensure the increase of solar-energy collection efficiency while simultaneously easing the fabrication of both monofacial and bifacial PV-cell based PV modules.

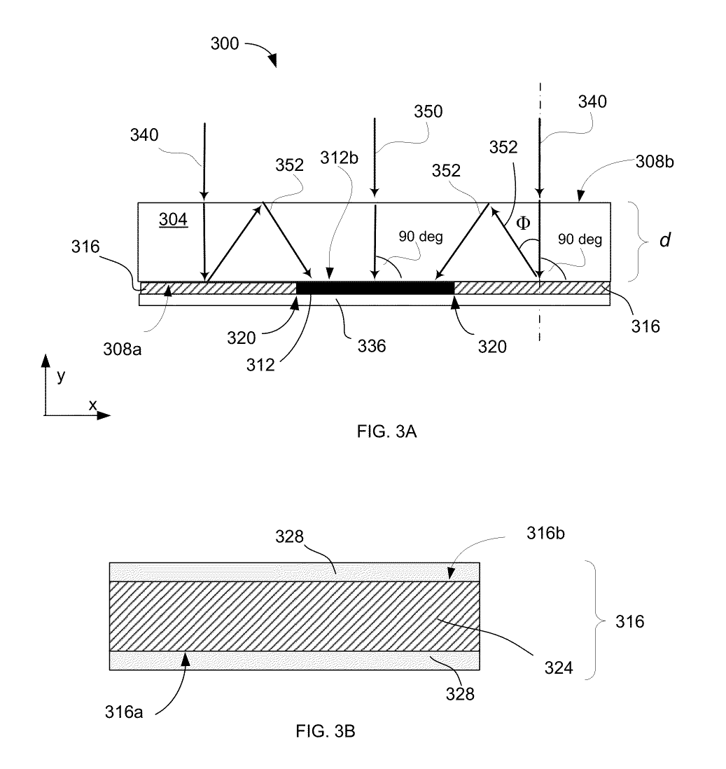

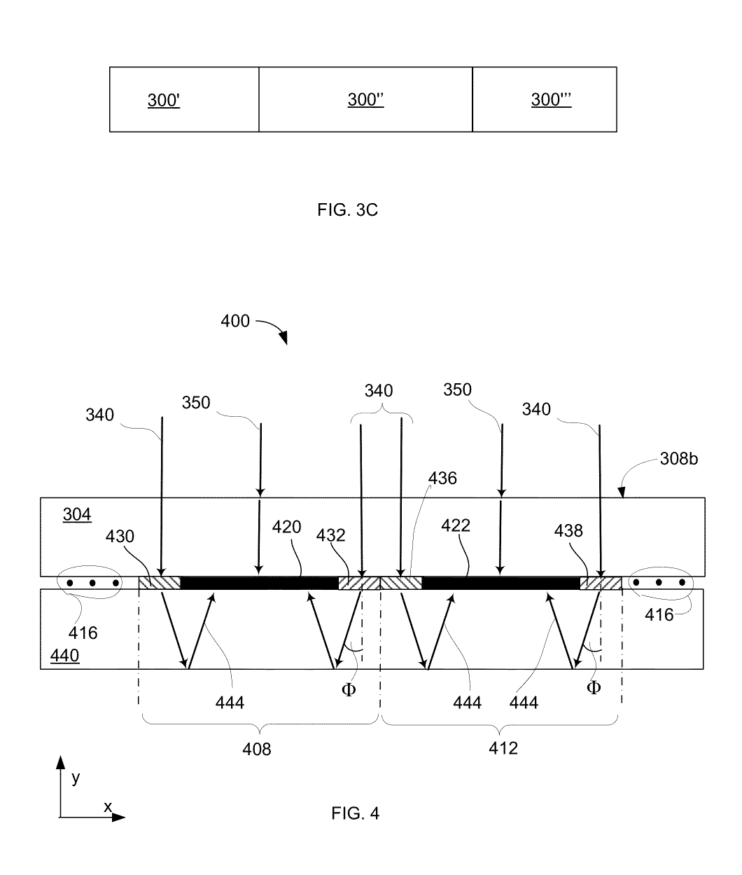

FIGS. 3A and 3B provide schematic illustrations to a discussion of a solar module according to an embodiment of the invention. Such solar module incorporates a reflective hologram in the encapsulant layer that is juxtaposed with a monofacial solar cell.

In the embodiment of FIG. 3A, a solar module 300 is shown to include a substantially transparent to light cover layer 304 (such as a glass or plastic plane-parallel plate or lite or substrate) of thickness d. To provide examples of a thickness range, in one embodiment d is about 1.1 mm, while in a related embodiment d is about 1.8 mm. The refractive index of the cover layer 304 is substantially spatially uniform across the lateral span of the cover 304. Against a first side 308a of the cover 304, a monofacial PV-cell 312 and a layer 316 are disposed, in a mutually adjoining and substantially co-planar fashion. Each of the PV-cell 312 and the layer 316 is in both physical and optical contact with the cover 304 such as to form an interface between the layers 316, 304 defined by a change of indices of refraction of these two layers. The monofacial PV-cell 312 is configured to photo-voltaically convert solar energy received at one of its two surfaces, specifically at a surface facing the cover 304. As shown, the PV-cell 312 has two adjoiningly neighboring layers 316, one on each side of the PV-cell 312, each of which is in physical contact with the cell 312 along a seam 320. In an alternative embodiment (not shown), the PV-cell 312 and at least one layer 316 may be separated from one another along the surface 308a such that a gap formed along the x-axis between the PV-cell 312 and the layer 316 in question defines a portion of the surface 308a that is not covered by either the PV-cell 312 or the layer 316. In another alternative embodiment (not shown), only one layer 316 is placed in proximity to the PV-cell 312 on one of its sides (either to the left or to the right of the cell 312). A second side 308b of the cover 304 optionally carries auxiliary thin film layer(s) such as anti-reflective or hard-oxide coatings (not shown for simplicity of illustration).

FIG. 3B shows in greater detail the constituent elements making up the layer 316. Each of the layer(s) 316 includes a holographic sub-layer 324 containing a diffractive structure. The diffractive structure may include, for example, a diffraction grating that has been holographically recorded in the layer 324. Accordingly, the layer 316 can be referred to as a hologram-containing layer. Additionally, the layer 316 includes an encapsulant material 328 disposed on a first side and a second side of the hologram-containing layer 324. Accordingly, the layer 316 is referred to as an encapsulant containing layer.

As the gelatin-based material is hydrophilic, changes in humidity of the ambient environment affect optical and/or geometrical parameters of the diffraction gratings recorded in such material (due to, for example, index changes and/or swelling of the material that has absorbed moisture, which would change the geometry of the hologram). Consequently, the operation of the diffraction gratings of the embodiments of light-concentrating devices of FIGS. 1, 2A, and 2B can be influenced and with it the PV conversion efficiency of light by the device can be affected depending on the procedure involved in fabrication of the device. For example, when the hologram- and encapsulant-containing layer 316 is laminated to the PV cell(s) 312 and the sandwiching covering layers 304 and 336 in a substantially short cycle of fabrication, the effect of the humidity in the ambient atmosphere may be reduced to the point that it is not visibly pronounced. However, if the layer 316 is intended to be pre-fabricated, transported and stored for use in laminating solar cells at some point that is delayed in time from the time of manufacture of this layer, precautions must be taken to ensure the continued fidelity of the hologram in the layer 316 because, as the layer 316 is stored, it is continuously affected by the ambient environment. Accordingly, in an embodiment where the holographic sub-layer 324 is a volume hologram recorded in dichromated gelatin, the hologram-carrying sub-layer 324 of the layer 316 is encapsulated within moisture impermeable, but optically transparent encapsulant layers 328 such as Surlyn (rather than EVA) or, more generally, a moisture impermeable ionomer. In a related embodiment, the encapsulant layers 328 may include a combination of both EVA and a moisture impermeable ionomer.

In further reference to FIG. 3A, the hologram- and encapsulant-containing layer 316 and the PV-cell 312 are optionally capped or overlayed with or carry a substantially moisture-impermeable backsheet 336 (such as, for example, a glass or plastic layer such as PET). The backsheet 336 is configured to provide additional protection of the diffraction-structure carrying layer(s) 316 from the ambient environment and additional structural support for the PV-cell 312.

In one embodiment, the encapsulant layer 328 is EVA (other encapsulant materials may be used, for example ionomers such as Surlyn available from DuPont & Co., Wilmington, Del.). In one embodiment (not shown), the hologram-carrying layer 324 includes two constituent sub-layers: a substrate layer of a plastic material such as PET, and a layer of dichromated gelatin carried by this plastic layer, in which the volume hologram is recorded. Other holographic media apart from gelatin may optionally be used (such as, for example, cellulose acetate film). In the event that the holographic layer 324 includes a volume holograph recorded in dichromated gelatin, the thickness of the layer 324 in one embodiment is about 100 microns.

In an alternative embodiment, the holographic layer 324 includes a stamped metal layer (for example, a foil of silver, gold, aluminum or another metal) onto which a holographic structure has been embossed or stamped. In such a case, the thickness of the layer 324 is smaller, for example on the order of 10 microns.

Where the layer 316 is juxtaposed with a monofacial PV cell, as in the case illustrated in FIG. 3A, at least one of the holographic portions 324 and the lower encapsulant layer 328 extends into and is a unitary structure with the backsheet 336. In such a case, both the lower encapsulant layer 328 of FIG. 3B and the backsheet layer 336 include a moisture impermeable, UV stable ionomer such as PET. The front side or top encapsulant layer 328 of FIG. 3B is also a moisture impermeable layer, e.g., Surlyn. It is contemplated that a flexible backsheet product according to an embodiment of the invention will be provided that includes backsheet 336 and encapsulated holographic 316 in a single, pre-patterned sheet adaptable for mounting the PV-cell(s) 312. These embodiments are fabricated by providing PET backsheet on which gelatin holograms are disposed, where the gelatin holograms are encapsulated by a Surlyn encapsulate layer. In these embodiments, the total thickness of the backsheet layer 336 and the encapsulated hologram-containing layer 316 is about 200 microns. Such product is flexible and lends itself to mass-production in a roll-to-roll process. Accordingly, a user could mount PV-cells to the holographic encapsulant/backsheet product, and thereafter use additional encapsulant material (which need not be moisture impermeable) to laminate the resulting structure to cover the layer 304. Additional adhesive layers can be provided on the glass side of the layer 316 outside of the area of the moisture impermeable encapsulant layer. Such adhesive layers are optional and are not shown for simplicity of illustration.

It is appreciated that in the final assembly such encapsulant material (not shown) also extends to fill, at least in art, the interfaces between the PV-cell 312 and the cover 304 and the layer 336. This is further addressed below in reference to FIG. 7.

In operation, a surface 308b of the cover 304 is directed towards the sun (or towards an auxiliary element delivering the sunlight to the embodiment 300) such that the incident light 340, 350 falls through the surface 308b onto the diffractive-structure layers 316 and the surface of the monofacial PV-cell 312 substantially perpendicularly. For example, in a related embodiment (not shown) in which the substrate 304 includes a glass wedge (i.e., in which the surfaces 308a,b are not parallel to one another), the front surface 308b of such wedge is appropriately oriented with respect to the incident light such as to ensure that light transmitted through the surface 308b impinges onto the surface 308a substantially normally.

In further reference to FIGS. 3A and 3B, the holographic grating structure 324 is appropriately arranged such that, upon interaction with the grating structure, the incident light 340 within the spectral region of interest diffracts towards the PV-cell 312 at an angle Φ that does not change appreciably with the small variation of the angle of incidence of light 340. The angle Φ is a function of the wavelength of incoming light 340 and the geometry of the grating structure 324. The grating is chosen such that, for the normally incident light, the diffracted angle Φ ensure the incidence of the diffracted beam onto a surface of the substrate 304 at an angle that is larger than the critical angle associated with the material of cover 304. As a result, the diffracted light 352 is further guided by total internal reflection towards the PV-cell 312 within the substrate 304. Light 350, penetrating through the substrate 304 directly towards the PV-cell 312, does not diffract at the hologram of the embodiment as such light does not interact with the layer 316 and, accordingly, with the hologram at the sub-layer 324.

It is appreciated that a general embodiment of the HPC may be configured as a multi-portion module or array of the elements each of which is configured in a fashion of the embodiment 300 of FIG. 3A. An example 370 of such multi-portion structure including three portions 300′, 300″, and 300′″ is shown schematically in FIG. 3C. Generally, different portions can have different extent of corresponding PV-cells and corresponding diffractive gratings. As shown in FIG. 3C, for example, the lateral extent of the portion 300″ is larger than lateral extent of either of the portions 300′ or 300′″. Multiple portions of the embodiment may optionally share at least one of the substrate (such as the substrate 304 of FIG. 3A) and the overlayer 336 covering the corresponding diffraction gratings and the PV-cells.

In the embodiment of FIGS. 3A and 3B, the hologram or grating-containing layer 324 may include a blazed grating dimensioned such that light 340 incident upon it is preferentially diffracted directed in a chosen direction and towards the PV-cell 312. It is contemplated that the structures such as the element 300 that contain the backsheet 336 and/or hologram and/or the encapsulant containing layer(s) 316 are used in an arrayed fashion, with active PV-cells on either side of the hologram. Accordingly, a grating structure of the layer 324 may include a non-blazed grating, enabling the diffraction of light towards both left and right, such that the diffracted light in both directions are be intercepted by adjacent PV-cells 312.

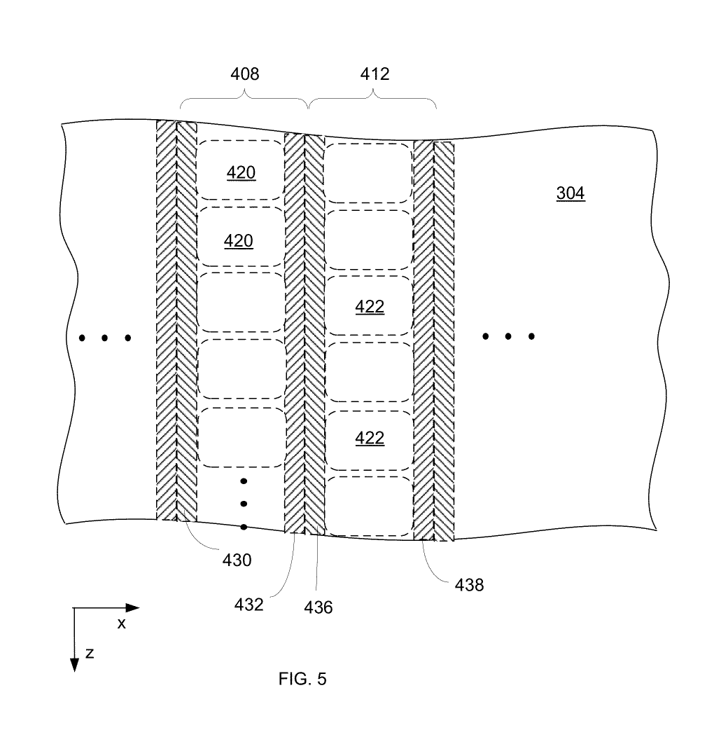

A related embodiment 400 of an HPC of the invention of FIG. 4 employs a bifacial PV-cell 404, adapted to convert solar energy received at either of its two surfaces. This embodiment includes an active layer (containing bifacial PV-cells surrounded by strips 430, 432, 436, 438 of layered material with holographically-defined gratings) that is sandwiched and/or laminated between the layers of encapsulating material(s) that may include optically-transparent substrates adapted to guide light diffracted on the gratings towards the bifacial PV-cells.

The embodiment 400 is a multi-portion (or multi-period) embodiment and, as shown, includes first and second portions 408, 412. Additional portions or periods, optionally present, are indicated with ellipses 416. Each of the portions or periods 408, 412 includes a corresponding bifacial PV-cell (420 or 422) that is surrounded by (and substantially co-planar with) respectively-corresponding holographically-recorded grating layers (430, 432) or (436, 438). The grating containing layers 430, 432, 436, 438 include, in one embodiment, transmissive bulk holographic diffraction gratings recorded in a dichromated gelatin layer. In a fashion similar to that of the embodiment 300 of FIG. 3A, the pairs of the grating-containing layers can be cooperated with the corresponding bifacial PV-cell (on the sides of such cell) with or without spatial gaps separating them from the cell. In a fashion similar to that of the embodiments of FIGS. 3A and 3B, each of the grating-containing layers 430, 432, 436, 438 may be incorporated into an encapsulant layer which is used laminate bifacial PV-cells 420, 422 together with the corresponding pairs of gratings (430, 432) and (436, 438) to front and back covers 304, 440. This is further discussed in reference to FIG. 7 below.

The covers 304, 440 are made of suitable optically transparent, UV stable, mechanically strong material(s) such as glass or polycarbonate, or acrylic, for example. When the covers 440, 304 are configured as sealing or encapsulating layers (for example, adhesively affixed to and over the PV-cells and the gratings), the periods 408, 412 of the overall embodiment 400 are protected from contact with the moisture of the ambient environment. In certain embodiments, PV-cells 420, 422 are in optical contact with the front and back covers 304, 440, which are in turn in optical contact with the grating layers 430, 432, 436, 438 via encapsulant layers not illustrated.

In further reference to the portion 408 of FIG. 4, for example, each of the holographically defined gratings 430, 432 is adapted to operate in transmission and oriented such that a portion of light 340 incident on these gratings is appropriately diffracted and guided, as shown by arrows 444, towards back surfaces of the corresponding PV-cell 420 by the encapsulating cover 440. Holographically defined diffraction gratings in layers 430, 432 diffract light at an angle Φ, with is above the critical angle for the material of the back cover 440 such that light 444 is guided to the back sides of cells 420, 422 by total internal reflection in the cover 440. At the same time, the bifacial PV-cells 420 directly absorbs light 350 that is incident onto the front surface 308b of the substrate 304 and traverses this substrate towards the PV-cells 420. The second portion 412 of the module 400 is configured to operate in a substantially similar fashion. A top view of the embodiment 400 is schematically shown in FIG. 5.

The diffraction gratings in layers 430, 432, 436, 438 are optionally structured as blazed gratings such that most of incident light that intercepts the gratings at normal incidence is preferentially directed in one direction (i.e., left or right, in −x or +x direction) towards the PV-cells 420, 422. It is contemplated that hologram-containing encapsulated structures will be used in an array, with active PV-cells on either side of the hologram. Accordingly, is a related embodiment it is acceptable to use a non-blazed grating structure, configured to diffract light in both the left and right directions (−x, +x directions) towards adjacent PV cell(s) at such angles that the diffracted light in both directions is intercepted by the adjacent PV-cells after reflection(s) within at least one of the covers 304, 440.

In further reference to FIGS. 4 and 5, in one related embodiment grating structures 430, 432, 436, 438 are embedded or incorporated in an ultra-violet (UV) stabilized ethyl vinyl acetate (EVA) with PV-cells 422, 424 laminated to the front and back covers 304, 440. This arrangement equips the diffraction-grating carrying elements 430, 432, 436, 438 with a flexible lamination layer.

In comparing the embodiments of the PV modules employing monofacial and bifacial PV cells it is contemplated that the requirement to seal sealing the diffraction-grating containing structures (such as the layer 324 of FIG. 3B, or the layers 430, 432, 436, 438 of FIG. 4) from ambient moisture may be relaxed in circumstances where a given grating structure is used with a bifacial PV cell. In other words, the individual grating-carrying elements 430, 432, 436, 438 of the embodiment 400 of FIG. 4 does not have to be necessarily sandwiched between the immediately adjoining encapsulating layers similarly to the layer 324 of FIG. 3B (which is sandwiched between the encapsulating layers 328). Indeed, in an embodiment 400 employing a bifacial PV cell, the underlying substrate 440 providing light-guidance to the bottom surface of a bifacial PV cell, additionally seals the grating-containing elements 430, 432, 436, 438 from the environment.

In an alternative embodiment (not shown), the grating structures 430, 432, 436, 438 are embedded in a standard EVA layer, which is then laminated to two optically transparent ionomer sheets such as Surlyn (similarly to the embodiment 300 of FIG. 3A), thereby ensuring not only the non-permeability of the lamination/encapsulating encasing of the gratings to moisture of the environment, but additionally making the overall laminated structure stable to the long-term UV-exposure. In yet another embodiment, at least one of the grating structures 430, 432, 436, 438 is embedded in a moisture-impermeable encapsulant layer with the use of a moisture permeable encapsulant or adhesive. In yet another embodiments, the elements 430, 432, 436, 438 are disposed in a gelatin layer, which is deposited on a flexible optically transparent layer such as PET that is more rigid then the gelatin layer. The gelatin layer is then encapsulated at its front and back sides with an encapsulant such as EVA or Surlyn. The bottom cover layer or substrate 400 does not have to be necessarily optically transparent (although the optical transparency is preferred). In this case, the corresponding embodiment can be implemented as a monofacial PV-cell application similar to that of FIG. 3A.

While the preferred embodiments of the present invention have been illustrated in detail, it should be apparent that modifications and adaptations to those embodiments may occur to one skilled in the art without departing from the scope of the present invention. For example, as illustrated by the alternative embodiment 700 of FIG. 7 employing the monofacial PV cell 312, the PV module incorporates first encapsulating layers 710a, 710b that are disposed over and under the PV cell 312 such as to separate the cell 312 from and laminate it with the substrate 304 and the flexible backsheet 336, while at least one of the holographic grating containing layers 328 on the sides of the cell 312 is embedded in a second encapsulating material, as discussed in reference to FIG. 3B. As a result, if viewed in a cross-sectional view along a plane 712 transverse to the PV-cell 312, the order of the layers starting from the bottom of the embodiment 700 is as follows: the flexible backsheet 336; the first encapsulating material 710b; the PV cell 312; the first encapsulating material 710a; the glass substrate 304. The first excapsulating material 710a, 710b, while shown to extend all the way along the substrate 304, generally does not necessarily extend over and/or under the grating element(s) 324. Accordingly, if viewed in a cross-sectional view along a plane 714 transverse to the grating element 324, the order of the layers starting from the bottom of the embodiment 700 is as follows: the flexible backsheet 336; the (optional) first encapsulating material 710b; the second encapsulating material 328; the grating element 324; the second encapsulating material 328; the (optional) first encapsulating material 710a; and the glass substrate 304. It is appreciated that in a related embodiment, the first and the second encapsulating materials may include the same encapsulating material. An embodiment of the PV module utilizing a bifacial PV cell may be structured in a fashion similar to that of the embodiment 700 of FIG. 7, when both the PV cell and the adjacently positioned holographic grating element are sandwiched in at least one of the first and second encapsulating materials that is disposed between the (PV cell or grating element) and the overlying and/or underlying substrates 304, 440.

In another related embodiment (not shown), a PV module may include an array of sub-modules such as those of the embodiments of FIG. 3A or 4, in which the sub-modules are both mechanically and electrically combined through flexible joints and, optionally, the overlying structural supporting element (such as the substrate 304) can be optionally appropriately shaped to include a dome-like structure (as discussed in the commonly assigned U.S. Ser. No. 13/675,855).

What is claimed is:

1. A photovoltaic (PV) module comprising:
a PV cell having a first photo-voltaically operable surface;
a first encapsulant material covering said first photo-voltaically operable surface;
a holographic grating element adjacent to and substantially coplanar with the PV cell;
a first optically transparent cover disposed in optical contact with the first encapsulant layer,
said first optically transparent cover extending over the holographic grating element,
said first optically transparent cover being dimensioned to reflect light, that has been received by the holographic grating element through the first optically transparent cover at about normal incidence, along a path defined by total internal reflection in said first optically transparent cover and ending at the first photo-voltaically operable surface,
a backsheet adhered to the PV cell along a surface opposite to the first photo-voltaically operable surface,
wherein said holographic grating element includes a holographic grating embedded in a second encapsulant material.

2. A PV module according to claim 1, wherein said holographic grating includes at least one of a volume hologram recorded in a gelatin material and a stamped metal hologram.

3. A PV module according to claim 1, wherein the second encapsulant material defines the backsheet.

4. A PV module according to claim 1, wherein the second encapsulant material is substantially moisture-impermeable.

5. A PV module according to claim 1, wherein said PV cell is a bifacial PV cell having a second photo-voltaically operable surface, and further comprising
a second optically-transparent cover disposed adjacently to said second photo-voltaically operable surface such as to extend along the holographic grating element,
said second optically-transparent cover being dimensioned to reflect light, that has been received by the holographic grating element through the first optically transparent cover at about normal incidence, along a path defined by total internal reflection in said second optically transparent cover and ending at the second photo-voltaically operable surface.

6. A PV module according to claim 4, wherein the holographic grating element includes a diffraction grating configured to operate both in reflection and transmission.

7. A PV module according to claim 5, comprising a gap between the holographic grating element and the PV cell, and further comprising an auxiliary holographic element at a surface of the second optically-transparent cover disposed to intersect light incident onto the gap through the first optically-transparent cover, said auxiliary holographic element adapted to redirect light so intersected towards the second photo-voltaically operable surface.

8. A PV module according to claim 1, wherein said PV cell is a monofacial PV cell.

9. A PV module according to claim 1, wherein the first encapsulant material does not extent over or under the holographic grating element.

10. A PV module according to claim 1, wherein the first and second encapsulant materials include the same material.

11. A PV module according to claim 1, comprising an array of PV cells and an array of corresponding holographic grating elements.

12. A photovoltaic (PV) module comprising:
a bifacial PV cell having first and second operational surfaces;
encapsulating materials disposed to cover said first and second surfaces;
first and second optical substrates positioned to sandwich said bifacial PV cell with encapsulating materials disposed thereon, each of said first and second optical substrates being in optical contact with a corresponding encapsulating material;
a holographic diffraction grating element configured to operate in transmission,
said diffraction grating element being adjacent to and substantially coplanar with the PV cell between the first and second covers,
said diffraction grating element configured to redirect light, incident thereon through the first cover at a substantially normal incidence, along a path defined by total internal reflection in the second cover and ending at the second operational surface.

13. A PV module according to claim 12, wherein said diffraction grating element is embedded in an encapsulating material that adheres said PV cell to the first and second substrates.

14. A PV module according to claim 12, wherein at least one of the encapsulating materials includes a substantially moisture-impermeable material.

15. A diffraction element comprising:
a layered optically-transparent structure including
a first photosensitive material containing a holographically-defined diffraction grating; and
second and third substantially moisture-impermeable materials sandwiching said first material therebetween.

16. A diffraction element according to claim 15, containing an array of said layered optically-transparent structures sharing at least one layer.
